(19) United States
(12) Patent Application Publication
(10) Pub. No.: US 2026/0269718 A1
(43) Pub. Date: Sep. 10, 2026

(54) POWER CONVERTER AND COIL PARTS

(71) Applicant: MITSUBISHI HEAVY INDUSTRIES, LTD., Tokyo (JP)

(72) Inventor: Tomoyuki MANABE, Tokyo (JP)

(73) Assignee: MITSUBISHI HEAVY INDUSTRIES, LTD., Tokyo (JP)

(21) Appl. No.: 19/166,647

(22) PCT Filed: Nov. 9, 2023
(86) PCT No.: PCT/JP2023/040409

§ 371 Date: Sep. 18, 2025

(30) Foreign Application Priority Data
Mar. 24, 2023 (JP) 2023-048003

(51) Int. Cl. H02M 3/00; H01F 27/24; H01F 27/28; H05K 7/20

(52) U.S. Cl. CPC H02M 3/003; H01F 27/24; H01F 27/28; H05K 7/209

(57) ABSTRACT

This power converter (100) is provided with: a casing (1) having a main body (10) inside which an accommodation space (S) is defined and a refrigerant flow path (11) that is formed in the main body; a coil unit (3) disposed in the accommodation space and cooled by a refrigerant flowing through the refrigerant flow path; and a power conversion circuit (2) disposed in the accommodation space and electrically connected to the coil unit. The coil unit is provided with: a coil case (30) formed of a heat-conductive material; a coil (33) including a core (33a) that is disposed in the coil case and a winding part (33b) in which a portion between one end and the other end connected to the power conversion circuit is wound around the core; and an insulating part (36) that is disposed in the coil case and electrically insulates the coil case from the coil. The main body has an opening portion (10h) where part of the refrigerant flow path opens to the accommodation space. The coil case is fixed to the main body so as to close the opening portion.

### TECHNICAL FIELD

The present disclosure relates to a power converter and coil parts.

Priority is claimed on Japanese Patent Application No. 2023-048003 filed on Mar. 24, 2023, the content of which is incorporated herein by reference.

### BACKGROUND ART

PTL 1 discloses a coil cooling structure including a first coil and a second coil, each having a circular shape and being wound around a core, a casing that accommodates the coils, and a cooling member that is disposed in a space having a substantially triangular cross section formed between the coils and the casing and in which a cooling medium passage is formed.

### CITATION LIST

### Patent Literature

[PTL 1] Japanese Unexamined Patent Application Publication No. 2006-156678

### SUMMARY OF INVENTION

### Technical Problem

In the field of power converters, there is a growing trend toward miniaturization of the entire device in order to improve added value. Accordingly, there is a demand for reducing the size of the coil in the device, but there is a problem in that the heat generation density increases due to self-heating of the coil itself as the coil is reduced in size.

The present disclosure has been made to solve the above-described problems, and an object of the present disclosure is to provide a power converter and coil parts capable of further cooling a coil.

### Solution to Problem

In order to solve the above problems, according to an aspect of the present disclosure, there is provided a power converter including: a casing that includes a main body portion defining an accommodation space on an inner side and a coolant flow path formed in the main body portion; coil parts that are disposed in the accommodation space and that are cooled by a refrigerant flowing through the coolant flow path; and a power conversion circuit that is disposed in the accommodation space and that is electrically connected to the coil parts, in which the coil parts include a coil case formed of a thermally conductive material, a coil having a core disposed in the coil case, and a winding portion in which a part between one end and the other end that are connected to the power conversion circuit is wound around the core, and an insulation portion disposed in the coil case and electrically insulating the coil case and the coil from each other, the main body portion has an opening that opens a part of the coolant flow path to the accommodation space, and the coil case is fixed to the main body portion to close the opening.

According to another aspect of the present disclosure, there is provided coil parts including: a coil case formed of a thermally conductive material; a coil that includes a core disposed in the coil case and having a cylindrical shape centered around a central axis, and a winding portion in which a part between one end and the other end is wound around the core; a first heat transfer portion formed of a thermally conductive material and extending in a columnar shape centered around the central axis on an inner side of the core in the coil case; and an insulation portion disposed in the coil case, and electrically insulating the coil case and the coil, as well as the coil and the first heat transfer portion from each other, in which the first heat transfer portion is connected to the coil case.

### Advantageous Effects of Invention

According to the present disclosure, it is possible to provide a power converter and coil parts that can further cool a coil.

### BRIEF DESCRIPTION OF DRAWINGS

FIG. 1 is a diagram showing a schematic configuration of a power converter according to an embodiment of the present disclosure in a cross section.

FIG. 2 is a view of coil parts as viewed from a direction of line II-II in FIG. 1.

FIG. 3 is a view showing coil parts according to another embodiment of the present disclosure in a cross section.

### DESCRIPTION OF EMBODIMENTS

Hereinafter, a power converter according to an embodiment of the present disclosure will be described with reference to the accompanying drawings.

### Embodiment of Power Converter

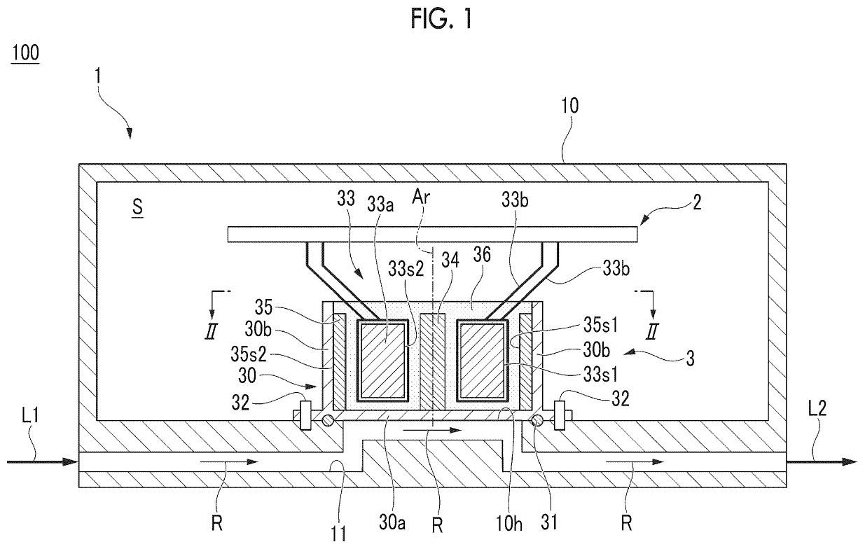

The power converter is, for example, a device that converts direct current power into three-phase alternating current power or the like. Examples of the power converter include an inverter used in a system such as a power plant and an inverter used for driving an alternating current rotary electric machine (motor) such as an electric vehicle. As shown in FIG. 1, a power converter 100 includes a casing 1, a power conversion circuit 2, and coil parts 3.

### (CASING)

The casing 1 is a housing for accommodating elements (the power conversion circuit 2 and the coil parts 3) constituting the power converter 100 on an inner side thereof. In addition, in the present embodiment, the casing 1 cools the coil parts 3 by using a liquid refrigerant R supplied from the outside of the casing 1. The casing 1 has a main body portion 10 and a coolant flow path 11.

### (Main Body Portion)

The main body portion 10 defines an accommodation space S, in which each of the above-described elements is disposed, on the inner side thereof. The main body portion 10 is formed of, for example, a metallic material. The material forming the main body portion 10 is not limited to a metallic material, and may be, for example, a synthetic resin material.

### (Coolant Flow Path)

The coolant flow path 11 is a passage through which the liquid refrigerant R flows. For example, water or the like is adopted as the liquid refrigerant R in the present embodiment. In addition, a liquid other than water may be adopted as the liquid refrigerant R. The coolant flow path 11 is formed in the main body portion 10. Specifically, the coolant flow path 11 is formed to extend inside a part of a wall member constituting the main body portion 10.

Lines L1 and L2 connected to a refrigerant supply device disposed outside the power converter 100 are connected to one end and the other end of the coolant flow path 11 opening on an outer surface of the main body portion 10. The liquid refrigerant R that has flowed into the coolant flow path 11 from the one end of the coolant flow path 11 through the line L1 from the refrigerant supply device flows through the coolant flow path 11, and then flows out from the other end of the coolant flow path 11 to the line L2 and returns to the refrigerant supply device through the line L2.

In addition, the main body portion 10 in the present embodiment has an opening 10h that opens a part of the coolant flow path 11 to the accommodation space S between the one end and the other end of the coolant flow path 11.

### (Power Conversion Circuit)

The power conversion circuit 2 is a circuit that converts the power input from the outside of the power converter 100. The power conversion circuit 2 is accommodated in the main body portion 10 of the casing 1. That is, the power conversion circuit 2 is disposed in the accommodation space S. The power conversion circuit 2 has, for example, a power supply (not shown) for performing an operation (for example, an operation of a control device and a switching operation of a power semiconductor element or the like) for converting the input power. In addition, for example, a bus bar (not shown) as an input/output terminal (conductor for connection) of the current is electrically connected to the power conversion circuit 2.

### (Coil Parts)

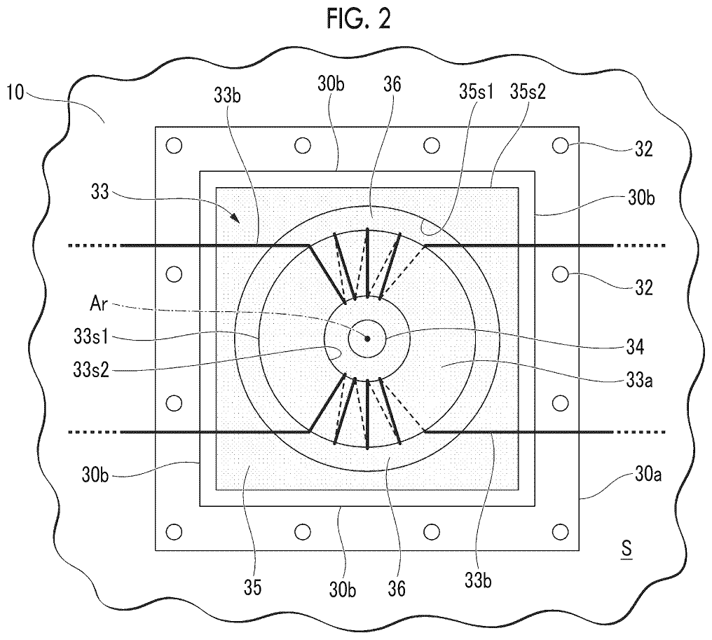

The coil parts 3 are electrically connected to the power conversion circuit 2. The coil parts 3 are accommodated in the main body portion 10 of the casing 1. That is, the coil parts 3 are disposed in the accommodation space S. As shown in FIGS. 1 and 2, the coil parts 3 include a coil case 30, a sealing part 31, a fastener 32, a coil 33, a first heat transfer portion 34, a second heat transfer portion 35, and an insulation portion 36.

### (Coil Case)

The coil case 30 is a housing for accommodating elements (the coils 33, the first heat transfer portion 34, the second heat transfer portion 35, and the insulation portion 36) constituting the coil parts 3 on the inner side thereof. The coil case 30 is formed of a thermally conductive material. For example, a metallic material containing aluminum is adopted as the thermally conductive material. In addition, a material other than aluminum may be adopted as the thermally conductive material forming the coil case 30. The coil case 30 is formed of a plurality of wall members. The coil case 30 has a bottom wall member 30a and a side wall member 30b.

The bottom wall member 30a has a plate shape. The bottom wall member 30a is fixed to the main body portion 10 to close the opening formed in the main body portion 10. Therefore, the liquid refrigerant R flowing through the coolant flow path 11 comes into contact with the bottom wall member 30a from a side opposite to the accommodation space S. The bottom wall member 30a is fixed to an inner surface of the main body portion 10 defining the accommodation space S by, for example, a plurality of fasteners 32 disposed at intervals along an outer edge portion of the main body portion 10. For example, a member such as a fastener or a bolt is adopted as the fastener 32. In FIGS. 1 and 2, a case of a bolt is shown as an example.

In addition, the sealing part 31 is disposed between the bottom wall member 30a and the main body portion 10. The sealing part 31 has, for example, an annular shape along the outer edge portion of the main body portion 10, and is disposed between the bottom wall member 30a and the main body portion 10 between the fastener 32 and the coolant flow path 11 in a direction in which the bottom wall member 30a having a plate shape extends. The sealing part 31 is in contact with the bottom wall member 30a and the main body portion 10, and is interposed between the bottom wall member 30a and the main body portion 10. For example, an O-ring is adopted as the sealing part 31.

The side wall member 30b has a plate shape. The side wall member 30b is provided integrally with the bottom wall member 30a to rise from the bottom wall member 30a. In the present embodiment, four side wall members 30b are provided on the bottom wall member 30a, and the four side wall members 30b define a space for accommodating a core 33a (to be described later) of the coil 33 together with the bottom wall member 30a. In FIG. 1, for convenience of illustration, only cross sections of two side wall members 30b are shown. Out of the four side wall members 30b defining a space for accommodating the core 33a of the coil 33, two adjacent side wall members 30b are integrally connected to each other (refer to FIG. 2). In the present embodiment, a rectangular parallelepiped-shaped space is defined by the four side wall members 30b and one bottom wall member 30a. The space is open toward a side opposite to the bottom wall member 30a.

### (Coil)

The coil 33 is a reactor electrically connected to a power supply of the power conversion circuit 2 or the like. The coil 33 in the present embodiment is a common mode coil for a power supply. The coil 33 includes the core 33a and a winding portion 33b.

The core 33a is a toroidal core disposed on the inside of the coil case 30. The core 33a is disposed at a position that does not come into contact with an inner surface of the coil case 30. The core 33a is a ferromagnetic body formed of, for example, a metallic material including iron. The core 33a has a cylindrical shape centered around a central axis Ar. The core 33a has an outer peripheral surface 33s1 facing an inner surface of the side wall member 30b on the inside of the coil case 30, and an inner peripheral surface 33s2 facing the inner side on the inside of the coil case 30. Both the outer peripheral surface 33s1 and the inner peripheral surface 33s2 have a cylindrical surface shape. The coil case 30 that accommodates the core 33a is fixed to the inner surface of the main body portion 10 in a direction in which the central axis Ar extends.

The winding portion 33b is, for example, an electrical lead in which one end and the other end are connected to a power supply of the power conversion circuit 2 or the like. A part between the one end and the other end of the winding portion 33b is wound around the core 33a. The winding portion 33b in the present embodiment is wound around the core 33a by cancel winding. The way of winding the winding portion 33b around the core 33a is not limited to the cancel winding, and may be a bifilar winding or the like.

The winding portion 33b is disposed at a position that does not come into contact with the inner surface of the coil case 30. The winding portion 33b is formed of, for example, a metallic material containing copper. In the present embodiment, two winding portions 33b are wound around the core 33a. As shown in FIG. 2, the parts wound around the core 33a in each of the two winding portions 33b are disposed to be separated from each other with the central axis Ar interposed therebetween. A part of the winding portion 33b that is not wound around the core 33a extends from the core 33a toward the power conversion circuit 2 through an opening of the coil case 30.

### (First Heat Transfer Portion)

The first heat transfer portion 34 is disposed on an inner side of the core 33a in the coil case 30. The first heat transfer portion 34 in the present embodiment extends in a columnar shape centered around the central axis Ar. Specifically, the first heat transfer portion 34 is disposed to penetrate the inner side of the core 33a in a direction in which the central axis Ar extends. An outer peripheral surface of the first heat transfer portion 34 and the inner peripheral surface 33s2 of the core 33a face each other at an interval in a direction in which the bottom wall member 30a extends. An end surface of the first heat transfer portion 34 on one side (one side in the direction in which the central axis Ar extends, lower side in FIG. 1) is connected to (in contact with) the bottom wall member 30a.

The first heat transfer portion 34 is formed of a thermally conductive material. For example, a metallic material containing aluminum is adopted as the thermally conductive material. In addition, a material other than aluminum may be adopted as the thermally conductive material forming the first heat transfer portion 34. It is preferable that the first heat transfer portion 34 is formed of a thermally conductive material having a higher thermal conductivity than the thermally conductive material forming the coil case 30.

### (Second Heat Transfer Portion)

The second heat transfer portion 35 is disposed on an outer side of the core 33a in the coil case 30. The second heat transfer portion 35 is disposed between the coil case 30 and the core 33a. The second heat transfer portion 35 in the present embodiment includes an inner peripheral surface 35s1 that has a cylindrical surface shape along the outer peripheral surface 33s1 of the core 33a, and an outer peripheral surface 35s2 that faces the inner surface of the side wall member 30b. The inner peripheral surface 35s1 of the second heat transfer portion 35 faces the outer peripheral surface 33s1 of the core 33a in a direction in which the bottom wall member 30a extends. The inner peripheral surface 35s1 of the second heat transfer portion 35 and the outer peripheral surface 33s1 of the core 33a face each other at an interval in a direction in which the bottom wall member 30a extends.

The second heat transfer portion 35 in the present embodiment has a shape in which a part having a columnar shape is hollowed out from a central part of a member having a rectangular parallelepiped shape. The inner peripheral surface 35s1 of the second heat transfer portion 35 is formed by the part having a columnar shape being hollowed out from a member having a rectangular parallelepiped shape. The outer peripheral surface 35s2 of the second heat transfer portion 35 is in contact with the inner surface of the coil case 30. An end surface of the second heat transfer portion 35 on one side (one side in the direction in which the central axis Ar extends, lower side in FIG. 1) is connected to (in contact with) the bottom wall member 30a.

The second heat transfer portion 35 is formed of a thermally conductive material. For example, a metallic material containing aluminum is adopted as the thermally conductive material. In addition, a material other than aluminum may be adopted as the thermally conductive material forming the second heat transfer portion 35. It is preferable that the second heat transfer portion 35 is formed of a thermally conductive material having a higher thermal conductivity than the thermally conductive material forming the coil case 30. The second heat transfer portion 35 in the present embodiment is formed of, for example, the same material as the first heat transfer portion 34.

### (Insulation Portion)

The insulation portion 36 is an insulation member that electrically insulates the elements (the coil 33, the first heat transfer portion 34, and the second heat transfer portion 35) accommodated in the coil case 30 from each other and electrically insulates each of the elements and the coil case 30 from each other. The insulation portion 36 is disposed in the coil case 30. The insulation portion 36 is disposed to fill a gap between the coil 33 and the coil case 30, a gap between the coil 33 and the first heat transfer portion 34, and a gap between the coil 33 and the second heat transfer portion 35. Therefore, the insulation portion 36 electrically insulates each of the coil 33 and the coil case 30, the coil 33 and the first heat transfer portion 34, and the coil 33 and the second heat transfer portion 35 from each other.

In the present embodiment, the insulation portion 36 is formed of a potting material. A liquid potting material is filled (potted) into the coil case 30 from the outside, and the filled potting material seals each element exposed in a space inside the coil case 30. The potting material filled inside the coil case 30 is cured over a predetermined time to form the insulation portion 36, and electrically insulates between the elements inside the coil case 30 and between each element and a space outside the coil case 30. For example, an insulating material such as a silicone gel or an epoxy resin is adopted as the potting material. That is, the insulation portion 36 is formed of an insulating material such as a silicone gel or an epoxy resin. In addition, a synthetic resin other than a silicone gel or an epoxy resin may be adopted as the potting material.

### (Operations and Effects)

When power is input to the power conversion circuit 2 and a current flows through the winding portion 33b of the coil parts 3, the core 33a of the coil 33 generates heat. The heat generated from the core 33a is conducted to the coil case 30 formed of a thermally conductive material via the insulation portion 36. The heat conducted to the coil case 30 is conducted through the coil case 30 toward the main body portion 10 of the casing 1 and reaches a part that closes the opening 10h that opens the coolant flow path 11. Since the part that closes the opening of the coolant flow path 11 is actively heat-exchanged with the liquid refrigerant R, the heat conducted to the part is removed by the liquid refrigerant R flowing through the coolant flow path 11.

In the above-described configuration, the coil case 30 formed of the thermally conductive material blocks the opening 10h of the main body portion 10 that opens the coolant flow path 11. Therefore, the coil case 30 itself is directly cooled by the liquid refrigerant R flowing through the coolant flow path 11. That is, the coil case 30 also serves as a heat sink of the coil parts 3. Accordingly, for example, compared to a case where a cooling heat sink or the like separate from the coil case 30 is provided in the coil case 30, the number of members to which heat generated from the core 33a of the coil 33 is conducted is smaller. Therefore, the coil 33 that has generated heat can be further cooled. As a result, the coil 33 can be further reduced in size. In addition, since a heat sink or the like for cooling the coil parts 3 is not required, the entire power converter 100 can be designed to be compact.

In addition, the inventors have found that the surface temperature of the core 33a (toroidal core) is uniformly distributed in a circumferential direction centered around the central axis Ar.

In the above-described configuration, the coil case 30 that accommodates the core 33a is fixed to the inner surface of the main body portion 10 in the direction in which the central axis Ar extends. Accordingly, a difference in length of a path of heat conducted from the core 33a to the coil case 30 in the circumferential direction centered around the central axis Ar is unlikely to occur. That is, the heat generated from the core 33a is unlikely to be unevenly distributed in the coil case 30. Therefore, the core 33a can be more uniformly cooled.

In addition, in the above-described configuration, the first heat transfer portion 34 having a columnar shape centered around the central axis Ar is disposed on the inner side of the core 33a, and the first heat transfer portion 34 is connected to a part that closes the opening 10h in the coil case 30. In this manner, for example, compared to a case where the insulation portion 36 or the like is simply disposed at a part on the inner side of the core 33a (a region surrounded by the inner peripheral surface 33s2 of the core 33a inside the coil case 30), the heat generated from the part on the inner side of the core 33a can be smoothly conducted toward the coil case 30. That is, the heat generated from the core 33a can be smoothly released to the coil case 30. Therefore, the coil 33 can be further cooled.

In addition, in the above-described configuration, the second heat transfer portion 35 disposed between the coil case 30 and the core 33a has the inner peripheral surface 35s1 having a cylindrical surface shape along the outer peripheral surface 33s1 of the core 33a. In this manner, for example, compared to a case where the coil parts 3 do not include the second heat transfer portion 35, the heat generated from the outer peripheral surface 33s1 of the core 33a can be conducted to the coil case 30 via the inner peripheral surface 35s1 of the second heat transfer portion 35. That is, the heat generated from the core 33a can be smoothly released to the coil case 30. Therefore, the coil 33 can be further cooled.

### (Other Embodiments)

While the embodiments of the present disclosure have been described above in detail with reference to the drawings, specific configurations are not limited to the configurations of each embodiment, and additions, omissions, and substitutions of the configurations and other changes can be made without departing from the concept of the present disclosure.

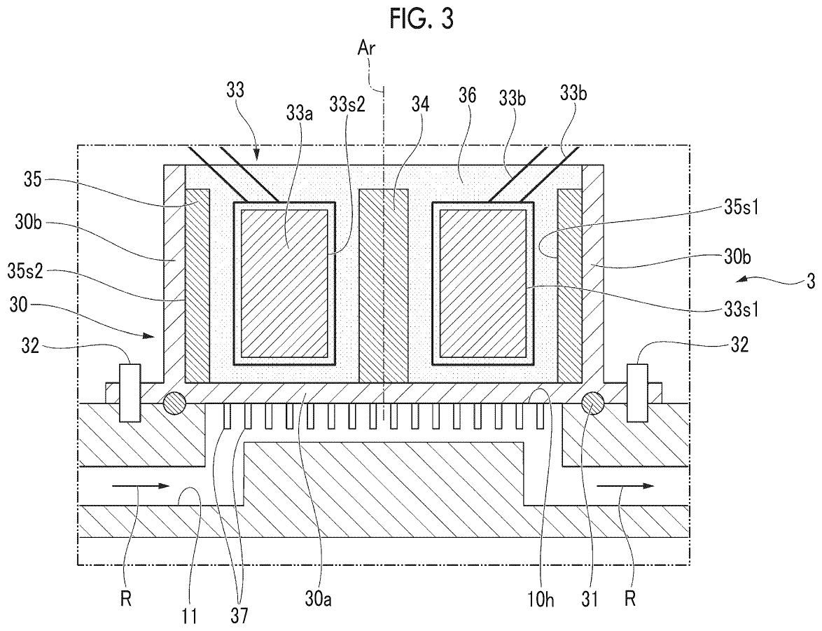

For example, as shown in FIG. 3, the coil parts 3 may further include a heat radiation portion 37 that is provided in the coil case 30 and that exchanges heat with the liquid refrigerant R flowing through the coolant flow path 11. In this case, the heat radiation portion 37 is a fin that is provided in the bottom wall member 30a of the coil case 30 and that extends from the bottom wall member 30a toward the coolant flow path 11. A plurality of the heat radiation portions 37 are disposed side by side at equal intervals in a direction in which the bottom wall member 30a extends. The heat radiation portion 37 is formed of a thermally conductive material. Each of the heat radiation portions 37 may have a panel shape disposed in a state perpendicular to the bottom wall member 30a, or may have a columnar shape disposed in a state perpendicular to the bottom wall member 30a.

In addition, the coil parts 3 may not include the second heat transfer portion 35. In this case, for example, the coil case 30 may have an inner peripheral surface formed in a cylindrical surface shape along the outer peripheral surface 33s1 of the core 33a. In addition, the coil case 30 may be formed in a cylindrical shape.

### Additional Note

The power converter 100 and the coil parts 3 described in the embodiment are understood as follows, for example.
(1) According to a first aspect, a power converter 100 includes: a casing 1 that includes a main body portion 10 defining an accommodation space S on an inner side and a coolant flow path 11 formed in the main body portion 10; coil parts 3 that are disposed in the accommodation space S and that are cooled by a refrigerant R flowing through the coolant flow path 11; and a power conversion circuit 2 that is disposed in the accommodation space S and that is electrically connected to the coil parts 3, in which the coil parts 3 include a coil case 30 formed of a thermally conductive material, a coil 33 having a core 33a disposed in the coil case 30, and a winding portion 33b in which a part between one end and the other end that are connected to the power conversion circuit 2 is wound around the core 33a, and an insulation portion 36 disposed in the coil case 30 and electrically insulating the coil case 30 and the coil 33 from each other, the main body portion 10 has an opening 10h that opens a part of the coolant flow path 11 to the accommodation space S, and the coil case 30 is fixed to the main body portion 10 to close the opening 10h.

Accordingly, for example, compared to a case where a cooling heat sink or the like separate from the coil case 30 is provided in the coil case 30, the number of members to which the heat generated from the core 33a of the coil 33 is conducted is smaller. Therefore, the coil 33 that has generated heat can be further cooled.
(2) In the power converter 100 according to a second aspect, which is the power converter 100 of the first aspect, the core 33a has a cylindrical shape centered around a central axis Ar, and the coil case 30 may be fixed to the main body portion 10 in a direction in which the central axis Ar extends.

Accordingly, a difference in length of a path of heat conducted from the core 33a to the coil case 30 in the circumferential direction centered around the central axis Ar is unlikely to occur. Therefore, the core 33a can be more uniformly cooled.
(3) In the power converter 100 according to a third aspect, which is the power converter 100 of the second aspect, the coil parts 3 may further include a first heat transfer portion 34 that is formed of a thermally conductive material and that extends in a columnar shape centered around the central axis Ar on an inner side of the core 33a in the coil case 30, the insulation portion 36 may further electrically insulate the coil 33 and the first heat transfer portion 34 from each other, and the first heat transfer portion 34 may be connected to a part that closes the opening 10h in the coil case 30.

In this manner, for example, compared to a case where the insulation portion 36 or the like is simply disposed at the part on the inner side of the core 33a, the heat generated from the part on the inner side of the core 33a can be smoothly conducted toward the coil case 30.
(4) In the power converter 100 according to a fourth aspect, which is the power converter 100 of the second or third aspect, the coil parts 3 may further include a second heat transfer portion 35 that is formed of a thermally conductive material and that is disposed between the coil case 30 and the core 33a, the insulation portion 36 may further electrically insulate the coil 33 and the second heat transfer portion 35 from each other, and the second heat transfer portion 35 may have an inner peripheral surface 35s1 that is formed in a cylindrical surface shape along an outer peripheral surface 33s1 of the core 33a and that is connected to the coil case 30.

In this manner, for example, compared to a case where the coil parts 3 do not include the second heat transfer portion 35, the heat generated from the outer peripheral surface 33s1 of the core 33a can be conducted to the coil case 30 via the inner peripheral surface 35s1 of the second heat transfer portion 35. That is, the heat generated from the core 33a can be smoothly released to the coil case 30.
(5) According to a fifth aspect, coil parts 3 include: a coil case 30 formed of a thermally conductive material; a coil 33 that includes a core 33a disposed in the coil case 30 and having a cylindrical shape centered around a central axis Ar, and a winding portion 33b in which a part between one end and the other end is wound around the core 33a; a first heat transfer portion 34 formed of a thermally conductive material and extending in a columnar shape centered around the central axis Ar on an inner side of the core 33a in the coil case 30; and an insulation portion 36 disposed in the coil case 30, and electrically insulating the coil case 30 and the coil 33, as well as the coil 33 and the first heat transfer portion 34 from each other, in which the first heat transfer portion 34 is connected to the coil case 30.

In this manner, the heat generated from the inner side of the core 33a can be released to the coil case 30 via the first heat transfer portion 34. Therefore, it is possible to suppress the retention of the heat generated from the core 33a inside the coil case 30. As a result, the coil 33 can be further cooled.

### INDUSTRIAL APPLICABILITY

According to the present disclosure, it is possible to provide a power converter and coil parts that can further cool a coil.

### REFERENCE SIGNS LIST

1 . . . Casing
2 . . . Power conversion circuit
3 . . . Coil parts
10 . . . Main body portion
10h . . . Opening
11 . . . Coolant flow path
30 . . . Coil case
30a . . . Bottom wall member
30b . . . Side wall member
31 . . . Sealing part
32 . . . Fastener
33 . . . Coil
33a . . . Core
33b . . . Winding portion
33s1, 35s2 . . . Outer peripheral surface
33s2, 35s1 . . . Inner peripheral surface
34 . . . First heat transfer portion
35 . . . Second heat transfer portion
36 . . . Insulation portion
37 . . . Heat radiation portion
100 . . . Power converter
Ar . . . Central axis
L1, L2 . . . Line
R . . . Liquid refrigerant
S . . . Accommodation space

1. A power converter comprising:
a casing that includes a main body portion defining an accommodation space on an inner side and a coolant flow path formed in the main body portion;
coil parts that are disposed in the accommodation space and that are cooled by a refrigerant flowing through the coolant flow path; and
a power conversion circuit that is disposed in the accommodation space and that is electrically connected to the coil parts, wherein
the coil parts include
a coil case formed of a thermally conductive material,
a coil having a core disposed in the coil case, and a winding portion in which a part between one end and the other end that are connected to the power conversion circuit is wound around the core, and
an insulation portion disposed in the coil case and electrically insulating the coil case and the coil from each other,
the main body portion has an opening that opens a part of the coolant flow path to the accommodation space, and
the coil case is fixed to the main body portion to close the opening.

2. The power converter according to claim 1, wherein
the core has a cylindrical shape centered around a central axis, and
the coil case is fixed to the main body portion in a direction in which the central axis extends.

3. The power converter according to claim 2, wherein
the coil parts further include
a first heat transfer portion that is formed of a thermally conductive material and that extends in a columnar shape centered around the central axis on an inner side of the core in the coil case,
the insulation portion further electrically insulates the coil and the first heat transfer portion from each other, and
the first heat transfer portion is connected to a part that closes the opening in the coil case.

4. The power converter according to claim 2, wherein
the coil parts further include
a second heat transfer portion that is formed of a thermally conductive material and that is disposed between the coil case and the core,
the insulation portion further electrically insulates the coil and the second heat transfer portion from each other, and
the second heat transfer portion has an inner peripheral surface that is formed in a cylindrical surface shape along an outer peripheral surface of the core and that is connected to the coil case.

5. Coil parts comprising:
a coil case formed of a thermally conductive material;
a coil that includes a core disposed in the coil case and having a cylindrical shape centered around a central axis, and a winding portion in which a part between one end and the other end is wound around the core;
a first heat transfer portion formed of a thermally conductive material and extending in a columnar shape centered around the central axis on an inner side of the core in the coil case; and
an insulation portion disposed in the coil case, and electrically insulating the coil case and the coil, as well as the coil and the first heat transfer portion from each other, wherein
the first heat transfer portion is connected to the coil case.
